(19) United States
(12) Patent Application Publication
(10) Pub. No.: US 2006/0148222 A1
(43) Pub. Date: Jul. 6, 2006

(54) Method for manufacturing semiconductor device

(76) Inventors: Myung Jin Jung, Seoul (KR); Dae Kyeun Kim, Yongin city (KR)

Correspondence Address: MCKENNA LONG & ALDRIDGE LLP;Song K. Jung, 1900 K Street, N.W., Washington, DC, 20006, US

(21) Appl. No.: 11/320,781

(22) Filed: Dec. 30, 2005

(30) Foreign Application Priority Data
Dec. 31, 2004 (KR) 10-2004-0117616

(51) Int. Cl. H01L 21/425; H01L 21/31

(52) U.S. Cl. 438/514; 438/780

(57) ABSTRACT

A method of manufacturing a semiconductor device prevents a shadow effect from occurring at the time of ion implantation by additionally performing a process of flowing a photoresist layer, which is used as a mask for ion implantation. The method includes forming a photoresist pattern over a strained silicon layer, performing a flowing process against the photoresist pattern, and implanting ions into the strained silicon layer using the photoresist pattern as a mask.

This application claims the benefit of Korean Application No. 10-2004-0117616, filed on Dec. 31, 2004, which is hereby incorporated by reference for all purposes as if fully set forth herein.

### BACKGROUND OF THE INVENTION

1. Field of the Invention

The present invention relates to a semiconductor device and more particularly to a method of manufacturing a semiconductor device in which a shadow effect is prevented at the time of an ion implantation by additionally performing a flowing process of a photoresist pattern which is used as a mask for ion implantation.

2. Discussion of the Related Art

Germanium (Ge) placed on a silicon (Si) substrate grows on the silicon (Si) substrate under a certain temperature condition. Then, by depositing a silicon (Si) layer on the germanium (Ge) and performing a thermal process, a strained silicon layer having the same lattice interval as the germanium (Ge) is obtained. The strained silicon layer has a lattice interval which is much greater than that of the related art silicon layer.

Generally, decreasing the size of semiconductor devices causes decreased mobility of electrons and holes. Accordingly, the strained silicon layer is a substrate type designed to enhance the mobility of the electrons and holes since it has a large lattice interval.

A strained silicon MOSFET is known as a semiconductor device employing the strained silicon substrate.

The strained silicon layer is formed by allowing germanium (Ge) to grow on a silicon (Si) layer so that the interval between silicon atoms is as large as the interval between germanium atoms. Then, silicon is allowed to grow thereon. The strained silicon layer is formed as a substrate having a lattice structure with a lattice interval much greater than that of a related art silicon.

A related art method of manufacturing a semiconductor device will be described with reference to the attached drawings.

FIG. 1 is a cross-sectional view of a semiconductor device during an ion implantation process in accordance with the related art method of manufacturing a semiconductor device.

As shown in FIG. 1, a silicon layer 3 is first prepared. Then, a strained silicon layer 5 having a lattice interval greater than that of the silicon layer 3 is formed by using the related art method.

Here, a stacked structure of the silicon layer 3 and strained silicon layer 5 constitutes a substrate 10. Subsequently, a gate insulating layer 11 is deposited on the strained silicon layer 5.

Next, a photoresist pattern 12 is formed by forming a photoresist layer on the gate insulating layer 11 and performing an exposure and developing process.

Then, impurity regions are formed in the substrate 10 by implanting impurity ions into the strained silicon layer 5 through exposed portions of the photoresist pattern 12. The ion implantation process may be performed by a tilt implantation method.

Since the strained silicon layer 5 has a large lattice interval, ions 20 are widely implanted around the photoresist pattern 12 and under the strained silicon layer 5, as indicated by “A” in FIG. 1. A phenomenon occurs in that the implanted ions are scattered around the photoresist pattern 12. This phenomenon is referred to as a shadow effect.

However, the related art method of manufacturing a semiconductor device has the following problems.

Since a transistor formed on the strained silicon layer has a lattice interval much greater than that of a general silicon, an improved mobility of electrons and holes exists. The strained silicon layer is designed to prevent deterioration in mobility of electrons and holes which is caused in processes resulting in sizes of 0.13 μm or less. However, since the strained silicon layer has a wide lattice interval, the ion implantation angle should be increased and thus the edge profile of the photoresist pattern becomes more important.

That is, in the related art method of manufacturing a semiconductor device employing the strained silicon layer as a substrate, since the strained silicon layer has a wide lattice interval, the ions are implanted into an area wider than a photoresist pattern used as a mask. Thus, it is difficult to control the ion implantation process.

### SUMMARY OF THE INVENTION

Accordingly, the present invention is directed to a method of manufacturing a semiconductor device that substantially obviates one or more problems due to limitations and disadvantages of the related art.

An advantage of the present invention is to provide a method of manufacturing a semiconductor device in which a shadow effect is prevented at the time of ion implantation by additionally performing a flowing process of a photoresist pattern which is used as a mask for ion implantation.

Additional features and advantages of the invention will be set forth in the description which follows, and will be apparent from the description, or may be learned by practice of the invention. The objectives and other advantages of the invention will be realized and attained by the structure and method particularly pointed out in the written description and claims hereof as well as the appended drawings.

According To achieve these and other advantages and in accordance with the purpose of the present invention, as embodied and broadly described, a method of manufacturing a semiconductor device includes forming a photoresist pattern over a strained silicon layer, performing flowing process against the photoresist pattern, and implanting ions into the strained silicon layer using the photoresist pattern as a mask.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principle of the invention. In the drawings:

FIG. 1 is a cross-sectional view of a semiconductor device during an ion implantation process of a related art method of manufacturing a semiconductor device; and

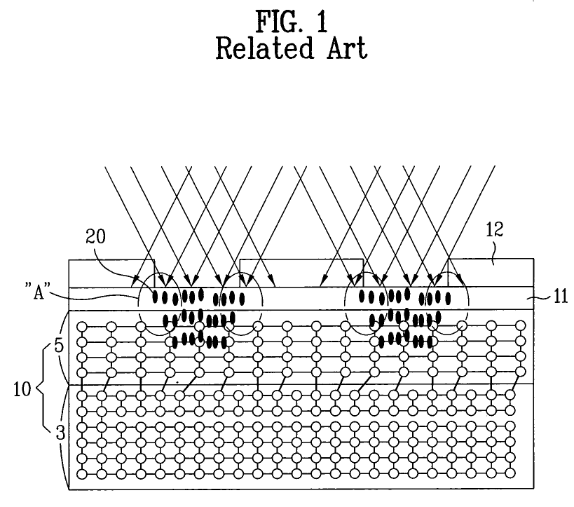

FIGS. 2A and 2B are cross-sectional views of a semiconductor device during an ion implantation process of a method of manufacturing a semiconductor device according to the present invention.

### DETAILED DESCRIPTION OF THE INVENTION

Reference will now be made in detail to exemplary embodiments of the present invention, examples of which are illustrated in the accompanying drawings. Wherever possible, the same reference numbers will be used throughout the drawings to refer to the same or similar parts.

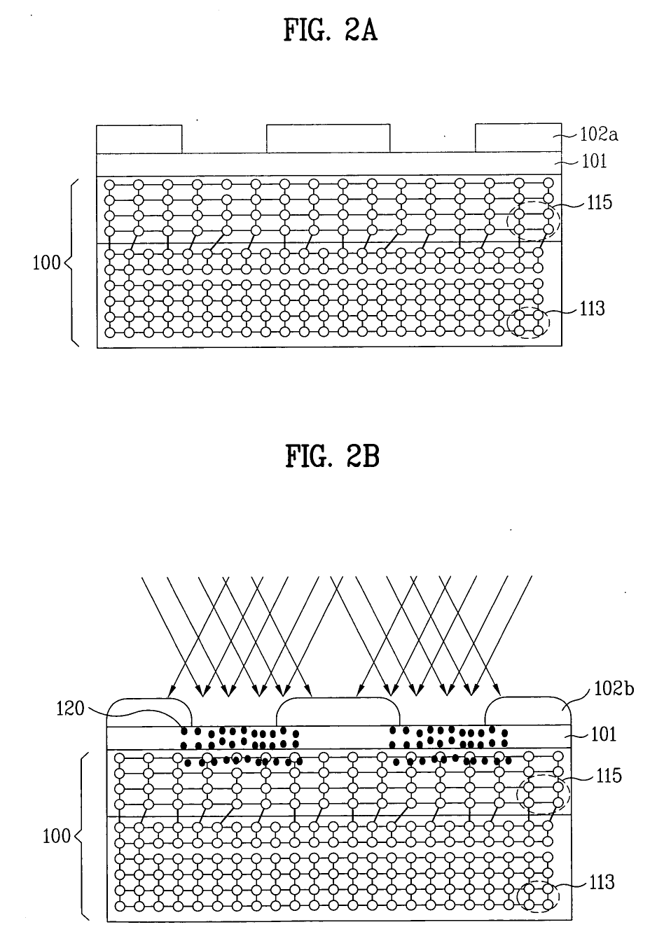

As shown in FIG. 2A, a first silicon layer 113 made of silicon (Si) is prepared.

Then, by allowing germanium (Ge) to grow on the first silicon layer 113, a second silicon layer 115 made of strained silicon having a lattice interval greater than that of the first silicon layer 113 is formed. Here, the stacked structure of the first silicon layer 113 and the second silicon layer 115 constitutes a substrate 100.

Next, a gate insulating layer 101 is deposited on the second silicon layer 115. According to an exemplary embodiment of the present invention, the gate insulating layer 101 comprises an oxide layer. Subsequently, a photoresist pattern 102a is formed by forming a photoresist layer(not shown) on the gate insulating layer 101 and performing an exposure and developing process to expose a portion of the second silicon layer 115 corresponding to source and drain regions.

Referring to FIG. 2B, by performing a flowing process against the photoresist pattern 102a through a thermal process, the edge profile of the photoresist pattern 102a is rounded to form photoresist pattern 102b. Since the second silicon layer 115 made of strained silicon has a large lattice interval, impurity regions formed in the substrate show lack of uniformity if a flat photoresist pattern is used. Accordingly, by changing the edge profile of the photoresist pattern 102a, the impurity regions 120 can be formed with uniformity. The deformed photoresist pattern 102b can be effectively used in an ion implantation process for forming junction regions, channels, pocket regions, source and drain regions, etc.

According to an exemplary embodiment of the present invention, the photoresist pattern 102a is formed of polymers having phenol as a main component so that the edge profile of the photoresist pattern 102a may be easily changed into a rounded shape through the flowing process, e.g., a thermal process.

Subsequently, ions are implanted into the exposed portions of the second silicon layer 115 by using the photoresist pattern 102b as a mask. Ion implantation may occur in a tilted and twisted manner by using a predetermined angle.

The rounded edge profile of the photoresist pattern 102b can prevent a shadow effect from occurring at the time of the ion implantation process. The rounded edge profile also can control the depth of the implanted ions, thereby preventing deterioration in performance of a transistor.

In the method of manufacturing a semiconductor device according to the present invention, the flowing of the photoresist pattern 102a deforms the edge profile of the photoresist pattern 102a into a round shape, thereby improving uniformity in diffusion of ions implanted into the impurity regions at the time of the ion implantation process. As a result, it is possible to reduce the shadow effect. The ion implantation process using the photoresist pattern having a round edge profile can be applied to forming source and drain regions, such as forming LDD regions and forming pocket regions.

The shape of the edge profile of the photoresist pattern can be controlled by adjusting the temperature for the thermal process or the time for the thermal process.

As described above, the method of manufacturing a semiconductor device according to the present invention has the following advantages.

It is possible to prevent disadvantages caused by the great gaps between lattices in the strained silicon layer. Thus, ions implanted in the ion implantation process are positioned at desired positions and are not affected by passing through the great gaps between lattices. Thus, deterioration in transistor performance and lack of uniformity in ion concentration are prevented, by additionally performing a process of flowing the photoresist pattern, which is used as a mask in the ion implantation process. Therefore, it is also possible to reduce the shadow effect.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A method of manufacturing a semiconductor device, the method comprising:
forming a photoresist pattern over a strained silicon layer;
performing a flowing process against the photoresist pattern; and
implanting ions into the strained silicon layer using the photoresist pattern as a mask.

2. The method according to claim 1, further comprising depositing a gate insulating layer on the strained silicon layer before forming the photoresist pattern.

3. The method according to claim 2, wherein the gate insulating layer comprises an oxide layer.

4. The method according to claim 1, wherein implanting ions is performed by a tilt implantation method.

5. The method according to claim 4, wherein a tilt angle of the tilt implantation method is determined by an edge profile of the photoresist pattern.

6. The method according to claim 1, wherein implanting ions is performed to each of source and drain regions of the strained silicon layer.

7. The method according to claim 1, wherein the flowing process is performed through a thermal process at a predetermined temperature.

8. The method according to claim 7, wherein the flowing process is performed by adjusting temperature during the thermal process to control an edge profile of the photoresist pattern.

9. The method according to claim 7, wherein the flowing process is performed by adjusting time of the thermal process to control an edge profile of the photoresist pattern.

10. The method according to claim 1, wherein the strained silicon layer is formed by allowing germanium to grow on a silicon layer.

11. The method according to claim 1, wherein the photoresist pattern is formed of a polymer.

12. The method according to claim 11, wherein the polymer comprises phenol.
